(19) United States
(12) Patent Application Publication
(10) Pub. No.: US 2008/0074047 A1
(43) Pub. Date: Mar. 27, 2008

(54) TANDEM ORGANIC ELECTROLUMINESCENT ELEMENT AND DISPLAY USE OF THE SAME

(76) Inventors: Chung-Chun Lee, Hsinchu (TW); Hsing-Chuan Li, Hsinchu (TW)

Correspondence Address: HOLLAND & KNIGHT LLP, 10 ST. JAMES AVENUE, 11th Floor, BOSTON, MA, 02116-3889, US

(21) Appl. No.: 11/671,608

(22) Filed: Feb. 6, 2007

(30) Foreign Application Priority Data
Sep. 22, 2006 (TW) 095135191

(51) Int. Cl. H01L 51/50

(52) U.S. Cl. 313/506; 313/504; 428/690; 428/917

(57) ABSTRACT

A tandem organic electroluminescent element for an organic electroluminescent display and a display using the tandem organic electroluminescent are provided. The tandem organic electroluminescent element comprises an anode, a cathode, a first high charge injection layer, a second high charge injection layer, and at least two organic electroluminescent units. Both the first high charge injection layer and the second high charge injection layer are disposed between the anode and the cathode. The first high charge injection layer comprises a first material and is adjacent to the anode. The second high charge injection layer comprises a second material and is adjacent to the cathode. At least two organic electroluminescent units are disposed between the first high charge injection layer and the second high charge injection layer.

### RELATED APPLICATION

This application claims the benefit from the priority of Taiwan Patent Application No. 095135191 filed on Sep. 22, 2006.

### BACKGROUND OF THE INVENTION

1. Field of the Invention

The present invention relates to a tandem organic electroluminescent element, and more particularly, to a tandem organic electroluminescent element for use in an organic electroluminescent display.

2. Descriptions of the Related Art

Because organic electroluminescent elements are known for their high brightness, thinness, lightness, self-luminosity, low power consumption, unlimited viewing angle, high contrast, wide temperature range, high luminous efficiency, easy manufacturing process and high response rate, they have not only become an important field in worldwide technological development, but have also been of great importance to the flat panel display industry. There are two types of technologies related to organic electroluminescent elements which depend on the type of organic electroluminescent materials used. The first type contains an organic light emitting layer prepared from small molecules, and is generally known as an organic light emitting diode (OLED) or an organic electroluminescence. The second type contains an organic light emitting layer prepared from π-conjugated polymers and is generally known as a polymer light emitting diode (PLED) or a light emitting polymer (LEP).

Generally, the organic electroluminescent element comprises an anode, a cathode, and light emitting unit(s) disposed between the anode and the cathode. The operating principle of the element is described as follows. Electrons and holes are injected and transmitted in the element under an externally added electric field. As the electrons and holes meet in the light emitting unit(s), they recombine into excitons, which transfer energy to light emitting molecules in the light emitting unit(s) under the electric field. The light emitting molecules then release the energy in the form of light. The light emitting unit of a conventional organic electroluminescent element comprises a multilayer structure with a hole transporting layer (HTL), a light emitting layer (EL), and an electron transporting layer (ETL). The method of manufacture is illustrated as follows. The HTL is formed by evaporation on the anode, which is made of indium tin oxide (ITO). Then, the EL and ETL are subsequently formed by evaporation. Finally, an electrode is formed on the ETL by evaporation as the cathode.

A conventional tandem organic electroluminescent element 1, adopting a multi-photon emission (MPE) technology, comprises an anode 11, a cathode 13, a plurality of light emitting layers 15, and charge generation layers 17, disposed between every two of the plurality of light emitting layers 15, as shown in FIG. 1. For improving the brightness of the element, an operating voltage would be increased, which lessens the lifetime of the tandem organic electroluminescent element that adapts the MPE technology and indirectly raises the cost and the power consumption.

Moreover, the connection interface between two organic electroluminescent elements of the tandem organic electroluminescent element, which are in tandem with each other, is unstable for an exceeding operation voltage requirement.

With the above illustrations, the current tandem organic electroluminescent elements have problems such as a high operation voltage and an unstable connection interface between organic electroluminescent units. These problems make the current tandem organic electroluminescent elements ill-fitted for this industrial field. Thus, the industrial field urgently requires a tandem organic electroluminescent element having low operation voltage and high stability of the connection interface between the units, and wherein the tandem organic electroluminescent element can prevent problems, such as high operation voltage and low stability of the connection interface between the units, and can further improve luminous efficiency, lessen power consumption, and reduce cost.

### SUMMARY OF THE INVENTION

An object of this invention is to provide a tandem organic electroluminescent element. The tandem organic electroluminescent element comprises an anode, a cathode, a first high charge injection layer, a second high charge injection layer, and at least two organic electroluminescent units. The first high charge injection layer is disposed between the anode and the cathode, adjacent to the anode, and comprises a first material. The second high charge injection layer is disposed between the anode and the cathode, adjacent to the cathode, and comprises a second material. The at least two organic electroluminescent units are disposed in tandem between the first high charge injection layer and the second high charge injection layer.

Another object of this invention is to provide a tandem organic electroluminescent display. The tandem organic electroluminescent display comprises the aforementioned tandem organic electroluminescent element and a thin film transistor. The thin film transistor is electrically connected to the tandem organic electroluminescent element.

The present invention adopts high charge injection layers, adjacent to the anode and the cathode, to stabilize the charge flow of the electrode and the organic electroluminescent units. Furthermore, the present invention effectively improves the luminous efficiency of the tandem organic electroluminescent element, decreases the power consumption, and reduces the cost without using an excessively large operation voltage.

The present invention will become apparent from the description of the preferred but non-limiting embodiments accompanying the appended drawings.

### BRIEF DESCRIPTION OF THE DRAWINGS

FIG. 1 shows a schematic view of the tandem organic electroluminescent element adopting the MPE technology;

FIG. 2 shows a schematic view of the tandem organic electroluminescent element in accordance with a first embodiment of the present invention;

FIG. 3A shows a comparison of voltage versus current density between the tandem organic electroluminescent elements having high charge injection layers with different materials;

FIG. 3B shows a comparison of voltage versus luminance between tandem organic electroluminescent elements having high charge injection layers with different materials;

FIG. 3C shows a comparison of luminance efficiency versus luminance between tandem organic electroluminescent elements having high charge injection layers with different materials;

FIG. 3D shows a comparison of luminance versus CIE value between the tandem organic electroluminescent elements having high charge injection layers with different materials; and

FIG. 4 shows a schematic view of the tandem organic electroluminescent element in accordance with a second embodiment of the present invention.

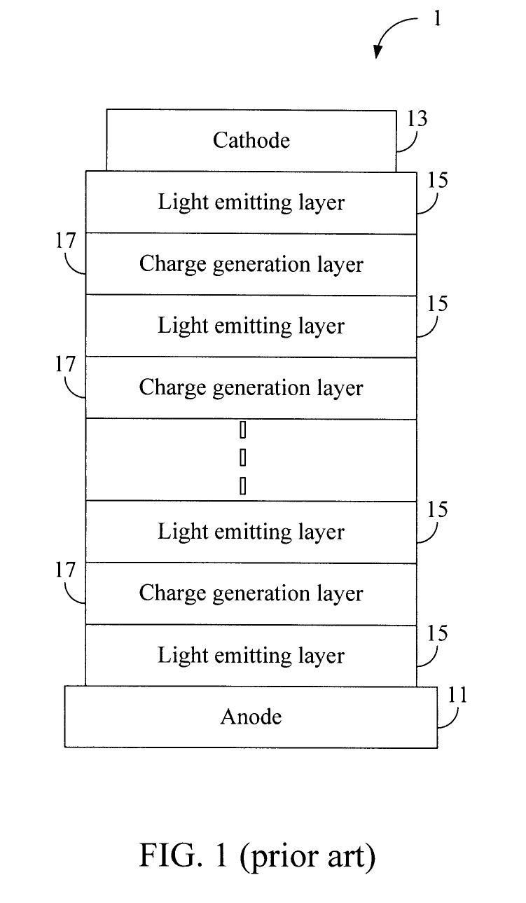

### DESCRIPTION OF THE PREFERRED EMBODIMENT

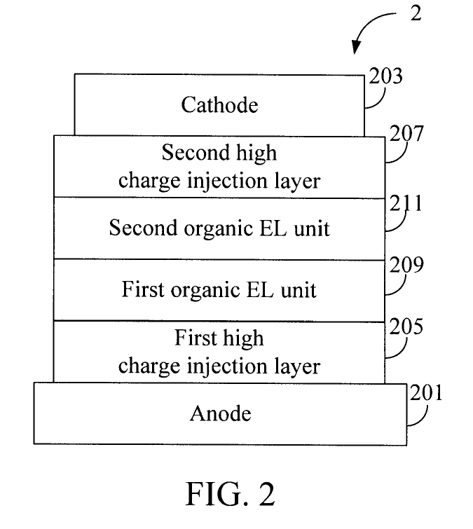

FIG. 2 shows a schematic view of the tandem organic electroluminescent element in accordance with a first embodiment of the present invention. The tandem organic electroluminescent element 2 comprises an anode 201, a cathode 203, a first high charge injection layer 205, a second high charge injection layer 207, a first organic electroluminescent unit 209, and a second organic electroluminescent unit 211. The first high charge injection layer 205 is disposed between the anode 201 and the cathode 203, and is adjacent to the anode 201. The first high charge injection layer 205 comprises a first material. The second high charge injection layer 207 is disposed between the anode 201 and the cathode 203, and is adjacent to the cathode 203. The second organic electroluminescent unit 211 comprises a second material. The first organic electroluminescent unit 209 and the second organic electroluminescent unit 211 are disposed in tandem between the first high charge injection layer 205 and the second high charge injection layer 207.

For the tandem organic electroluminescent element 2, the anode 201 comprises material(s) with a relatively high work function, and the cathode 203 comprises material(s) with a relatively low work function. One of the cathode 203 and the anode 201 is a transparent electrode, while the other is either a transparent electrode or an opaque electrode. For example, the transparent electrode of ITO (Indium Tin Oxide) may be used as the anode 201, and materials, such as magnesium, magnesium-silver alloy, calcium, lithium-aluminum alloy, etc., may be used as the material of the cathode 203.

Carrier mobility of the first high charge injection layer 205 and the second high charge injection layer 207 of the present invention should be at least 1×10⁻⁴ cm²/Vs for providing enough charge injection ability. That is, the first high charge injection layer 205 has a hole mobility equal to or more than 1×10⁻⁴ cm²/Vs, and the second high charge injection layer 207 has an electron mobility equal to or more than 1×10⁻⁴ cm²/Vs. Preferably, the carrier mobility of the high charge injection layers should be higher than that of any ETL of the tandem organic electroluminescent element.

The first high charge injection layer 205 comprises the first material and a first substrate, and the second high charge injection layer 207 comprises the second material and a second substrate. The first substrate and the second substrate can be the same or different organic substances, and the first material and the second material can be the same or different and independently selected from the group consisting of organic substances and inorganic substances.

Generally speaking, the first substrate and the second substrate usually adopt different materials for hole and electron transportation ability, respectively. However, some organic materials have characteristics for promoting both hole and electron transportation, and are suitable materials for both the first substrate and the second substrate. For example, the materials suitable for both the first substrate and the second substrate may comprise but are not limited to: copper phthalocyanine (CuPc), 2,9-dimethyl-4,7-diphenyl-1,10-phenanthroline (BCP), carbazole derivatives like 4,4-bis(9-dicarbazolyl)-biphenyl (CBP), distyrylarylene derivatives like 4,4′-bis(2,2′-diphenyl vinyl)-1,1′-biphenyl (DPVBi), anthracene derivatives, and fluorene derivatives. Other suitable materials comprise all kinds of metal phthalocyanines, including but not limited to, ZnPc, MgPc, and PbPc.

As mentioned above, the first high charge injection layer 205 is adjacent to the anode 201 so the more preferable material thereof is organic compounds with high electron withdrawing ability. Preferably, the material of the first substrate is aromatic tertiary amine, which comprises at least one trivalent nitrogen that is bonded to a carbon atom, and has at least one aromatic ring. The aromatic tertiary amine can be an arylamine, such as a monoaryl amine, a diarylamine, a triarylamine, or a polymeric arylamine. Other suitable triarylamines substituted with one or more vinyl radicals and/or comprising at least one active hydrogen-containing group can also been used. More preferred aromatic tertiary amines are those which include at least two aromatic tertiary amine portions, for example, N,N′-di(naphthalene-1-yl)-N,N′-diphenyl-benzidine (NPB), N,N,N′,N′-tetranaphthyl-benzidine (TNB), N,N′-diphenyl-N,N′-bis(3-methylphenyl)-1-1′-biphenyl-4-4′-diamine (TPD), N,N′-diphenyl-N,N′-bis(1-naphthyl)-1-1′-biphenyl-4,4″-diamine (α-NPD), 4,4′,4″-tris(N,N-diphenyl-amino)-triphenylamine (TDATA), 4,4′,4″-tris(3-methyl-phenyl-phenylamino)-triphenylamine (MTDATA), poly(vinyltriphenylamine (PVT), and poly(n-vinylcarbazole) (PVK).

As mentioned above, the second high charge injection layer 207 is adjacent to the cathode 203 so the more preferable material thereof is organic compounds with high electron transportation ability. Preferred materials of the second substrate are metal chelated oxinoid compounds (also referred as 8-quinolinol or 8-hydroxyquinoline), such as tris(8-hydroxyquinoline) aluminum. The materials of the second substrate can also be butadiene derivatives, triazines derivatives, hydroxyquinoline derivatives, benzazole derivatives, silole derivatives like 2,5-bis(2′,2″-bipridin-6-yl)-1,1-dimethyl-3,4-diphenyl silacyclopentadien, 2,5-bis(1-naphthyl)-1,3,4-oxadiazole (BND), 2-(4-biphenylyl)-5-(4-tert-butyl phenyl)-1,3,4-oxadiazole (PBD), 1,3-bis[(4-tert-butylphenyl)-1,3,4-oxadiazolyl]phenylene (OXD-7), 1,2,4-triazole derivative (TAZ), 4,7-diphenyl-1,10-phenanthroline (BPhen), 2,9-dimethyl-4,7-diphenyl-1,10-phenanthroline (BCP), 1,3,5-tris(N-phenyl-benzimidazol-2-yl)benzene (TPBI), Tris(8-hydroxyquinoline)aluminum (Alq), bis(10-hydroxybenzo[h]quinolinato)beryllium (BeBq), bis(2-methyl-8-quinolinolato)(para-phenyl-phenolato)aluminum (III) (BAlq), and bis[2-(2-hydroxyphenyl)benzoxazolate]zinc.

The inorganic substances suitable for the first material include a p type dopant, and preferably are a first metal or its compound having a work function of more than 4.2 eV The hole transport rate of the first high charge injection layer 205 can be increased by doping the p type dopant thereinto. Most metals can be the p type dopant except for rare earth metals and the alloys thereof. Preferably, the p type dopant is a metal selected from the group consisting of gold, silver, copper, zinc, cobalt, nickel, compounds thereof, and compounds thereof. The metal compound can be an organometallic complex, an organic salt, an inorganic salt, an oxide, or a halide.

As mentioned above, an organic substance can be used as the first material. For example the first material can be provided by, but is not limited to, 2,3,5,6-tetrafluoro-7,7,8,8- tetracyanoquinodimethane (F4-TCNQ) and/or 7,7,8,8-tetracyanoquinodimethane (TCNQ).

The inorganic substances suitable for the second material comprise an n type dopant, and a second metal or its compound having a work function of less than 4.2 eV is preferable. The electron transport rate of the second high charge injection layer 207 can be increased by doping the n type dopant thereinto. The second metal can be an alkali metal, such as lithium, sodium, potassium, rubidium, or cesium, an alkaline earth metal, such as magnesium, calcium, strontium, or barium, a rare earth metal, such as lanthanum, samarium, europium, thorium, dysprosium, erbium, or ytterbium, or an alloy of the aforementioned metals, such as an aluminum alloy or an indium alloy. The metal compound can be an organometallic complex, an organic salt, an inorganic salt, an oxide, or a halide.

The first organic electroluminescent unit 209 and the second organic electroluminescent unit 211 can be the same or different in their elements, structures, photochromes, materials, and manufacturing processes, as long as they can provide the desired electron transport rate and hole transport rate, respectively. The first organic electroluminescent unit 209 and the second organic electroluminescent unit 211 can be any known organic electroluminescent unit and comprises a light emitting layer and an optional multilayer structure comprising one or more of the following layers: an EIL, an ETL, a HTL, a HIL, an electron blocking layer (EBL) and a hole blocking layer (HBL). For example, the multilayer structure can be, but not limited to, HTL/EL/ETL, HIL/HTL/EL/ETL, HIL/HTL/EL/ETL/EIL, HIL/HTL/EBL or HBL/EL/ETL/EIL, HIL/HTL/EL/HBL/ETL/EIL, etc. Optionally, a high charge injection layer can be disposed between two electroluminescent units. For instance, if both the structures of the first organic electroluminescent unit 209 and the second organic electroluminescent unit 211 are HTL/EL/ETL, a high charge injection layer can be added between the ETL of the first unit 209 and the HTL of the second unit 211. Moreover, a charge generation layer (CGL) can be inserted into the first unit 209 and the second unit 211 for transferring electrical energy into light energy. With the photoelectric effect, electrons can be generated to improve the luminous efficiency of the element and provide multi-photon emission embodiments.

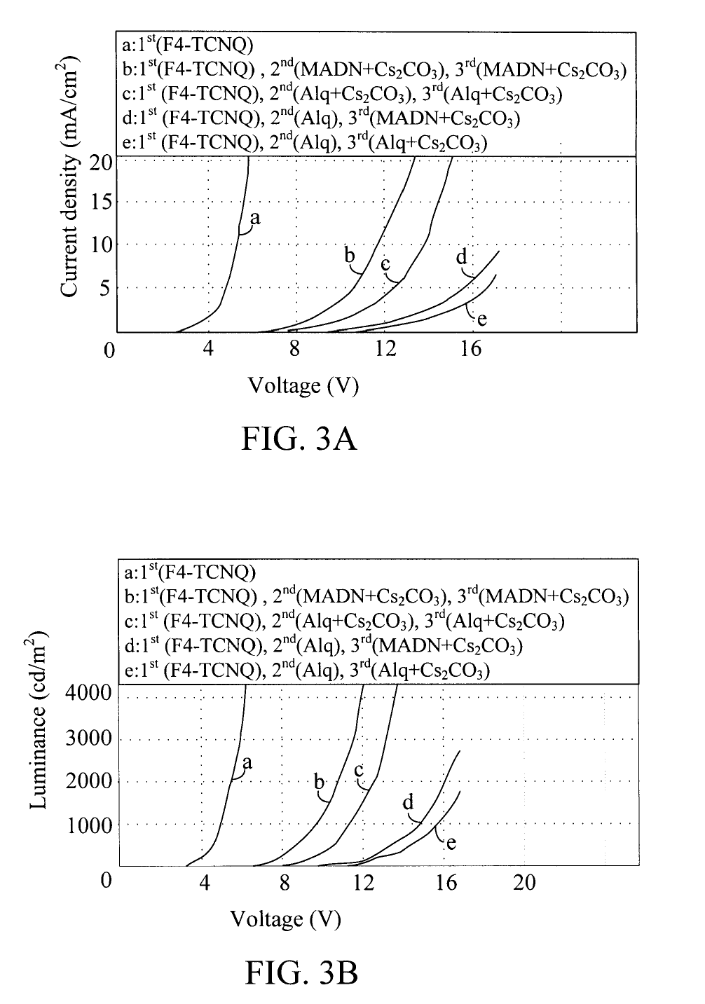

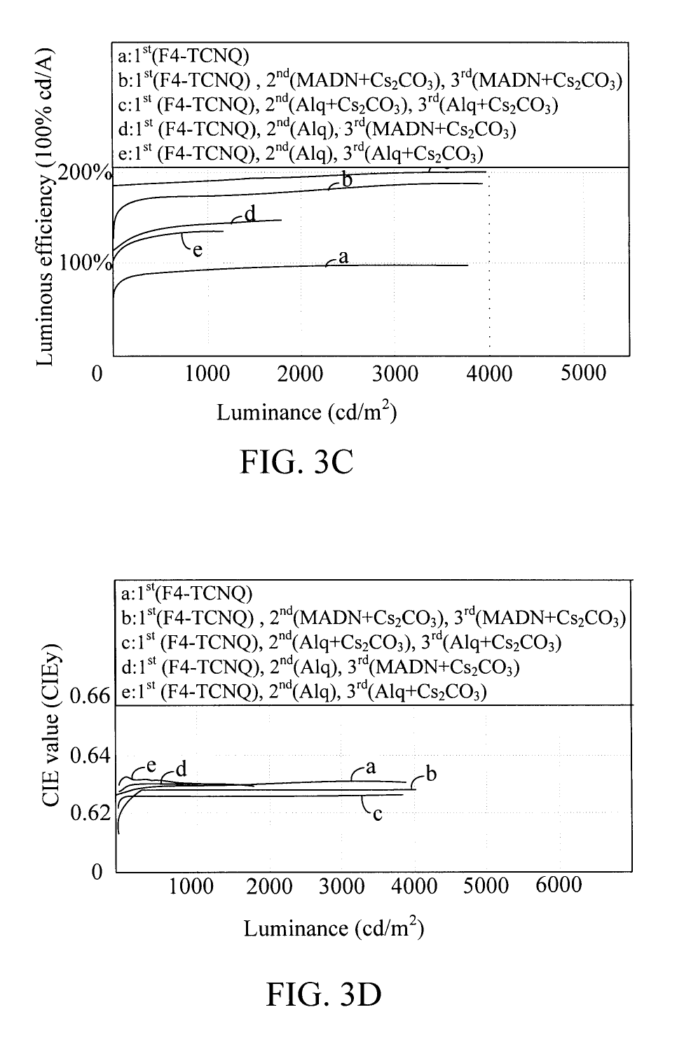

The efficacy of the present invention is further illustrated in FIG. 3A to FIG. 3D. FIG. 3A shows a voltage versus current density relationship in graphic form. The horizontal axis and the longitudinal axis represent voltage (volt) and current density (mm·A/cm²) of the organic electroluminescent element, respectively. FIG. 3B shows a voltage versus luminance relationship in graphic form. The horizontal axis and the longitudinal axis represent voltage (volt) and luminance (cd/m²) of the organic electroluminescent element, respectively. FIG. 3C shows a luminous efficiency versus luminance relationship in graphic form. The horizontal axis represents luminance (cd/m²) of the organic electroluminescent element and the longitudinal axis represent the percentage of organic electroluminescent element when the maximum luminance of the organic electroluminescent element, which comprises a single organic electroluminescent unit, is defined as 100%. FIG. 3D shows a luminance versus CIE value relationship in graphic form. The horizontal axis and the longitudinal axis represent luminance (cd/m²) and CIEy value (i.e. photochrome), respectively.

Referring to FIG. 3A to FIG. 3D, line a stands for the performance of an organic electroluminescent element including a single organic electroluminescent unit, and a first high charge injection layer disposed between the anode and the single organic electroluminescent unit, and wherein the first high charge injection layer is a HIL doped with F4-TCNQ. Line b stands for the performance of a tandem organic electroluminescent element 2 including two organic electroluminescent units, a first high charge injection layer, disposed between the anode and the organic electroluminescent unit, adjacent to the anode, a second high charge injection layer, disposed between the cathode and the organic electroluminescent unit, adjacent to the cathode, and a third high charge injection layer between two organic electroluminescent units, and wherein the first high charge injection layer is a HIL doped with F4-TCNQ, and both the second and the third high charge injection layers use MADN doped with Cs₂CO₃. Line c stands for the performance of a tandem organic electroluminescent element 2 having two organic electroluminescent units, and the tandem organic electroluminescent element 2 adopts the first high charge injection layer, the second high charge injection layer, and the third high charge injection layer as line b. However, the materials of the second high charge injection layer and the third high charge injection layer are Alq doped with Cs₂CO₃. Line d stands for the performance of a tandem organic electroluminescent element 2 having two organic electroluminescent units, and the tandem organic electroluminescent element 2 adopts the first high charge injection layer and the third high charge injection layer as line b. However, the material of the layer between the cathode and the organic electroluminescent unit adjacent to the cathode is undoped Alq. Line e stands for the performance of a tandem organic electroluminescent element 2 having two organic electroluminescent units, and the tandem organic electroluminescent element 2 adopts the first high charge injection layer as line d and adopts undoped Alq between the cathode and the organic electroluminescent unit adjacent to the cathode as line d. However, the materials of the third high charge injection layer between the two organic electroluminescent units is Alq doped with Cs₂CO₃. The charge injection ability of the undoped Alq is merely 1×10⁻⁶ cm²/Vs, and is less than that (at least 1×10⁻⁴ cm²/Vs) of the requirement of the present invention.

As shown in FIG. 3A to FIG. 3D, in comparison with an organic electroluminescent element having a single organic electroluminescent unit and a high charge injection layer between the anode and the organic electroluminescent unit, the tandem organic electroluminescent element that adopts a high charge injection layer between organic electroluminescent units provides an enhanced luminous efficiency and an equivalent photochrome efficiency, however, requires a much higher voltage (comparing line d, line e with line a). If adopting high charge injection layers between the anode and the organic electroluminescent unit adjacent to the anode and between the cathode and the organic electroluminescent unit adjacent to the cathode, the tandem organic electroluminescent element would provide a better luminous efficiency and equivalent photochrome efficiency under a proper voltage.

With the aforementioned results, the tandem organic electroluminescent element 2 of the present invention can improve luminous efficiency effectively without an overlarge operation voltage. In addition, there are high charge injection layers in the tandem organic electroluminescent element 2 of the present invention, and the charges flow steadily and the connection interface between the units is therefore stable.

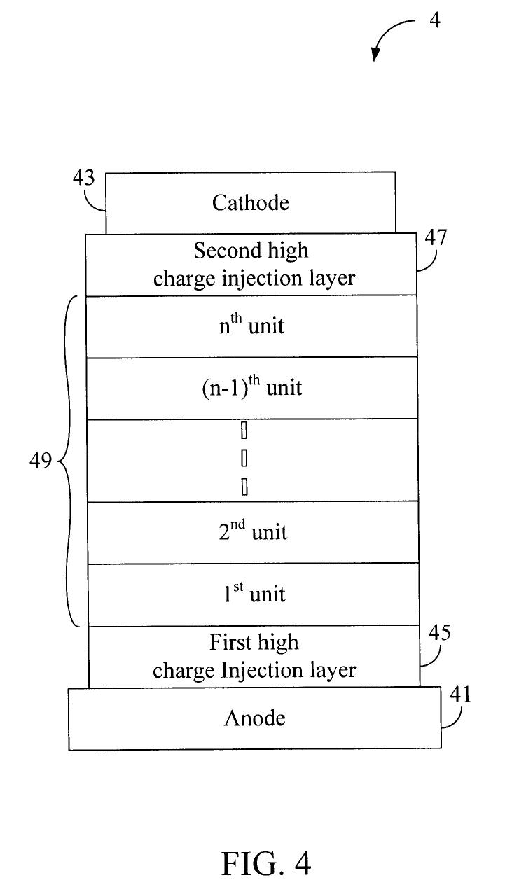

The embodiments illustrated for the present invention show a tandem organic electroluminescent element comprising an anode, a cathode, a first high charge injection layer, a second high charge injection layer, a first organic electroluminescent unit, and a second organic electroluminescent unit. Those skilled in this field would appreciate the workability of a second embodiment of the present invention according to the aforementioned embodiment, wherein a tandem organic electroluminescent element 4 comprises an anode 41, a cathode 43, a first high charge injection layer 45, a second high charge injection layer 47, and a plurality of organic electroluminescent units 49 as shown in FIG. 4.

A third embodiment of the present invention is an organic electroluminescent display. The organic electroluminescent display comprises a plurality of tandem organic electroluminescent elements as recited above and a substrate. The substrate comprises a plurality of thin film transistors, wherein the plurality of thin film transistors is electrically connected to a plurality of electrodes of the tandem organic electroluminescent elements. With this tandem organic electroluminescent element, the present invention prevents low luminous efficiency, high power consumption, and increased cost resulting from excessively high operation voltage and instability of the connection interface of the units. Moreover, the tandem organic electroluminescent element further has the characteristic of a high carrier transport rate.

The above disclosure is related to the detailed technical contents and inventive features thereof. Those skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A tandem organic electroluminescent element, comprising:
an anode;
a cathode;
a first high charge injection layer, disposed between the anode and the cathode, comprising a first material;
a second high charge injection layer, disposed between the anode and the cathode, comprising a second material; and
at least two organic electroluminescent units disposed in tandem between the first high charge injection layer and the second high charge injection layer,
wherein the first high charge injection layer is adjacent to the anode, and the second high charge injection layer is adjacent to the cathode.

2. The tandem organic electroluminescent element as claimed in claim 1, wherein the first high charge injection layer has a hole mobility more than 1×10⁻⁴ cm²/Vs.

3. The tandem organic electroluminescent element as claimed in claim 1, wherein the second high charge injection layer has an electron mobility more than 1×10⁻⁴ cm²/Vs.

4. The tandem organic electroluminescent element as claimed in claim 1, wherein the first material is selected from the group consisting of organic substances and inorganic substances.

5. The tandem organic electroluminescent element as claimed in claim 1, wherein the second material is selected from the group consisting of organic substances and inorganic substances.

6. The tandem organic electroluminescent element as claimed in claim 1, wherein the first material comprises a p type dopant, and the second material comprises an n type dopant.

7. The tandem organic electroluminescent element as claimed in claim 6, wherein the p type dopant is a first metal or compounds thereof having a work function of more than 4.2 eV, and the n type dopant is a second metal or compounds thereof having a work function of less than 4.2 eV.

8. The tandem organic electroluminescent element as claimed in claim 1, wherein the first high charge injection layer comprises MADN doped with Cs₂CO₃, Alq doped with Cs₂CO₃, or NPD doped with F4-TCNQ.

9. The tandem organic electroluminescent element as claimed in claim 1, wherein the second high charge injection layer comprises MADN doped with Cs₂CO₃, Alq doped with Cs₂CO₃, or NPD doped with F4-TCNQ.

10. A tandem organic electroluminescent display, comprising:
the organic electroluminescent element as claimed in claim 1; and
a thin film transistor, electrically connected to the tandem organic electroluminescent element.
